(19) United States
(12) Patent Application Publication
(10) Pub. No.: US 2006/0249072 A1
(43) Pub. Date: Nov. 9, 2006

(54) Method of synthesizing a fluoride growth material for improved outgassing

(76) Inventors: Frank J. Csillag, Hudson, OH (US); Christopher D. Jones, Amherst, NH (US)

Correspondence Address: DON W. BULSON (SAINT-GOBAIN CORP.);RENNER, OTTO, BOISSELLE & SKLAR, LLP, 1621 EUCLID AVENUE, 19TH FLOOR, CLEVELAND, OH, 44115, US

(21) Appl. No.: 11/122,703

(22) Filed: May 5, 2005

(51) Int. Cl. C30B 21/04; C01B 33/26; C30B 13/00; C30B 28/08

(52) U.S. Cl. 117/43; 423/328.2

(57) ABSTRACT

Improved contaminant removal from alkaline- or alkali-earth metal fluoride crystal growth material can be obtained by coprecipitating an alkaline- or alkali-earth metal fluoride with a scavenging agent during synthesis of the fluoride growth material. The coprecipitation of the alkaline- or alkali-earth metal fluoride and scavenging agent can be performed using at least one of chloride, nitrate, hydroxide and carbonate salts of the alkaline- or alkali-earth metal fluoride and scavenging agent. This provides a more intimate mixture or dispersion of the scavenging agent in solid solution or as a mechanical mixture with the alkaline- or alkali-earth metal fluoride for improved outgassing and fewer trapped impurities, leading to improved radiation hardness and bulk absorption.

The invention herein described relates generally to a method of synthesizing a growth material used to form fluoride crystals and particularly single crystals of alkali- and alkaline-earth fluorides, such as calcium fluoride, magnesium fluoride, strontium fluoride, barium fluoride, lithium fluoride, sodium fluoride, and mixtures thereof, that are particularly suited for use as optical elements having excellent transmission properties.

### BACKGROUND

The growth of large essentially single crystal ingots of various inorganic salts for use as optical bodies has been the focus of much attention over the past several decades. Among the salts especially suited for use as lenses over a wide range of wavelengths of radiation, are the alkaline-earth metal halides. Most preferred are the fluorides of barium and calcium.

For many applications including, in particular, lenses used at wavelengths of 157 and 193 nm in photolithography equipment, a highly transparent, strain free and radiation hard single crystal, particularly of calcium or barium fluoride, is required. One of the problems of producing a radiation hard material through liquid phase growth using the Stockbarger crystal growth method or other methods, such as Bridgman, Czochralski, or Kyropolous, is to thoroughly outgas the starting charge of calcium or barium fluoride such that little if any measurable oxygen, moisture or other undesirable impurities remain when growing the crystal in a crucible.

Some degassing occurs when the calcium or barium fluoride charge in the crucible is heated under vacuum and the absorbed species leaves by desorption. Although this heating under vacuum removes many of the unwanted contaminants, further improvements to the degassing are achieved when scavenging agents are added. Typical scavenging agents include metal fluorides, hydrogen fluoride gas, polytetrafluoroethylene and carbon tetrafluoride. Perhaps the most widely used scavenging agent is lead fluoride.

Lead fluoride is typically added to a calcium or barium fluoride charge in quantities from 1 to 3 weight percent. The lead fluoride is added as a powder and is mechanically mixed with the calcium or barium fluoride such that it is uniformly dispersed to the extent possible.

At high temperature, typically greater than 600° C., the lead fluoride begins to substantially volatize. Any water, oxygen, sulfur, sulfate species, as examples, can react with the lead fluorides and be exhausted as volatile lead compounds. This reduces the impurities in the charge and makes for products with improved characteristics of transparency, strain and radiation hardness.

Unfortunately, many of the contaminants in the calcium and barium fluorides may not be on the surface of the powder or may not reach the surface for discharge before the charge is molten and the crystal is grown. Consequently, impurities can still be trapped in the crystal, thereby degrading the final product.

### SUMMARY OF THE INVENTION

The present invention provides a fluoride crystal with improved characteristics of transparency, strain and radiation hardness, and an improved technique that further reduces the potential for trapped impurities when applied to prior crystal growth techniques.

In accordance with the invention, a fluoride crystal has a bulk absorption equal to or better than 0.015%/cm at a wavelength of 193 nm, more preferably equal to or better than 0.014%/cm at a wavelength of 193 nm, and still more preferably equal to or better than 0.013%/cm at a wavelength of 193 nm.

In accordance with the invention, improved contaminant removal is obtained by coprecipitating an alkaline- or alkali-earth metal fluoride with a scavenging agent during synthesis of the fluoride growth material. The coprecipitation of the alkaline- or alkali-earth metal fluoride and scavenging agent can be performed using at least one of chloride, nitrate, hydroxide, and carbonate salts of the alkaline- or alkali-earth metal fluoride and scavenging agent. The resulting solid solution of the alkaline- or alkali-earth metal fluoride and scavenger results in a material that has improved outgassing properties and fewer trapped impurities in the grown crystal. As is known, coprecipitation is the simultaneous precipitation of more than one type of compound during precipitate formation by one or more of the following phenomena: surface adsorption, mixed-crystal formation, occlusion, and/or mechanical entrapment.

Accordingly, the invention provides a method of synthesizing a growth material used to form fluoride crystals (e.g. calcium fluoride, magnesium fluoride, strontium fluoride, barium fluoride, lithium fluoride, sodium fluoride, or mixtures thereof), wherein a fluoride of an alkaline- or alkali-earth metal is coprecipitated from solution with a scavenger to form after separation from solution an intimate dispersion of the scavenger, which could be a solid solution with the alkaline- or alkali-earth metal fluoride, or a fine mixture of both the scavenger and the alkaline- or alkali-earth metal fluoride. The scavenger can be a metal fluoride, and more particularly a metal fluoride selected from the group consisting of lead or zinc fluoride.

In a preferred embodiment, coprecipitation of alkaline- or alkali-earth metal fluoride and the scavenger is performed using at least one of the chloride, nitrate, hydroxide, or carbonate salts of the alkaline- or alkali-earth metal and scavenger. The chloride, nitrate, hydroxide, and carbonate salts of the alkaline- or alkali-earth metal and scavenger can be reacted in solution with hydrofluoric acid, or an aqueous fluoride salt such as ammonium fluoride, ammonium bifluoride, or mixtures thereof, to coprecipitate the alkaline- or alkali-earth metal fluoride and the scavenger, after which the coprecipitate is separated from the supernatant. The coprecipitate preferably is then dried to provide a finely divided powder of the coprecipitated crystals that can be loaded into a growth crucible and heated in an enclosed space for outgassing impurities such as oxygen. Thereafter, the now highly pure growth material can be heated until molten, and then cooled to grow a fluoride crystal from the molten growth material.

Depending on the outgassing conditions, the lead fluoride and oxide may leave the material before and/or after the melting of the material. The use of an intimate solid solution or fine mechanical mixture of the scavenger and the alkaline- or alkali-earth fluoride improves the ability to remove impurities such as oxygen from the powder as the scavenger is better dispersed through the material than mechanical mixing alone and therefore is more likely to come into contact with, and react with, the impurity. The use of a solid intimate solution has the added benefit of delaying the removal of some of the scavenger until higher temperatures than mechanical mixtures alone, where the scavenger is more favorable to react with oxygen.

In accordance with a further aspect of the invention, there is provided a method of growing a fluoride crystal, wherein a fluoride of an alkaline- or alkali-earth metal is coprecipitated from solution with a scavenger to form after separation an intimate dispersion of the scavenger with the alkaline- or alkali-earth metal fluoride to improve radiation hardness, and the intimate dispersion is used to grow the fluoride crystal.

The foregoing and other features of the invention are hereinafter more fully described and particularly pointed out in the claims, the following description setting forth in detail certain illustrative embodiments of the invention, these being indicative, however, of but a few of the various ways in which the principles of the invention may be employed.

### DETAILED DESCRIPTION

As above indicated, the present invention provides an improved technique that further reduces the potential for trapped impurities, and one that can improve the desired stoichiometry, resulting in improved radiation hardness in the grown crystal when applied to prior crystal growth techniques. This technique can be applied to conventional methods for synthesizing alkaline- or alkali-earth metal fluoride growth stock and particularly those methods that employ a scavenger to remove impurities, in particular oxygen, from the growth stock, as is desired to provide a radiation hard, highly transmissive crystal. Radiation hardness may be defined as resistance to damage in a crystal resulting from exposure to energy that reduces the transmission of the crystal.

Heretofore, a scavenger, such as lead fluoride, would be added to the alkaline- or alkali-earth metal fluoride, such as a calcium fluoride, magnesium fluoride, strontium fluoride, barium fluoride, lithium fluoride, and mixtures thereof, charge in quantities from 1 to 3 weight percent. The lead fluoride typically is added as a powder and is mechanically mixed with the alkaline- or alkali-earth fluoride such that it is uniformly dispersed to the extent possible. At high temperature, typically greater than 600° C., the lead fluoride begins to substantially volatize. Any oxygen, water, sulfur, sulfate species, as examples, can react with the lead fluorides and be exhausted as volatile lead compounds. This reduces the impurities in the charge and makes for products with improved characteristics of transparency, strain and radiation hardness.

Many of the contaminants in the alkaline- or alkali-earth fluorides may not be on the surface of the powder, or may not reach the surface, for discharge before the charge is molten and the crystal is grown. Consequently, impurities can still be trapped in the crystal, thereby degrading the final product.

The present invention provides a method for discharging the previously unreachable contaminants. This is accomplished by coprecipitating from a solution the alkaline- or alkali-earth metal and a scavenger to form after separation an intimate dispersion (which could be a solid solution or a well dispersed mechanical mixture) of the scavenger in the alkaline- or alkali-earth metal fluoride. The scavenger can be a metal fluoride, such as lead fluoride. The scavenger could range from 0.001 to 50% wt, while it is preferred to use 1-10% wt, more preferred 1-5% wt, and most preferred is 1-3% wt.

Coprecipitation of alkaline- or alkali-earth metal fluoride and the scavenger can be performed using at least one of the chloride, nitride, hydroxide, or carbonate salts of the alkaline- or alkali-earth metal and scavenger. The chloride, nitride, hydroxide, or carbonate salts of the alkaline- or alkali-earth metal and scavenger can be reacted in solution with hydrofluoric acid, or an aqueous fluoride salt such as ammonium fluoride, ammonium bifluoride, or mixtures thereof, to coprecipitate the alkaline- or alkali-earth metal fluoride and the scavenger, after which the coprecipitate is separated from solution. The coprecipitate preferably is then dried to provide a finely divided powder of the coprecipitated crystals that can be loaded into a growth crucible and heated in an enclosed space for outgassing impurities including, in particular, oxygen, using known outgassing techniques.

Typically, the growth material is heated to less than its melt temperature, for example to a temperature in the range of 600-1200° C. At the same time, the reaction gases are exhausted from the enclosed space which typically is maintained under vacuum conditions. The outgassing typically will be conducted for at least several hours and generally for periods of from one day to one month. Thereafter, the now highly pure growth material can be heated until molten, and then cooled to grow a fluoride crystal from the molten growth material according to known crystal growth techniques, such as the Stockbarger, Bridgman, Czochralski or Kyropolous processes. The result is a crystal having improved radiation hardness and reduced absorption of wavelengths from at least 157 nm and higher.

During outgassing, discharge of the previously unreachable contaminants can be further improved by bubbling a scavenger gas through a melt of the alkaline- or alkali-earth metal halides to improve the purity of the melt by removing more volatile metal halides and oxygen contained within the melt. By reacting after the raw material has melted, any oxygen or metal impurities trapped in the raw material is free to react with the scavenger gas. Additionally, any deviation from desired stoichiometry is corrected, as the alkaline- or alkali-earth metal halides can react with additional halides made available by the scavenger gas.

This gas introduction process is described in U.S. patent application Ser. No. 10/977,523 entitled “Method of Purifying Alkaline-Earth and Alkali-Earth Halides for Crystal Growth” and filed on Oct. 28, 2004, which application is hereby incorporated herein by reference in its entirety. In accordance therewith, a powder coprecipitated as above described can be heated in a growth furnace until it is molten under vacuum, and a scavenger gas can be injected into the melt. The scavenger gas can be supplied through a tube inserted into the melt. The tube should be made of a material, such as graphite, that does not react with the molten fluoride or the scavenger gas. The tube, for example, can be a hollow graphite tube that is inserted through a probe hole in a wall of the growth furnace. The graphite tube can be connected to source of the scavenger gas and the rate of bubbling can be controlled by the gas flow. The end of the tube may or may not be equipped with a gas diffuser, as desired. The tube can be inserted into the melt until the end of the tube that exhausts the gas is near the bottom of the melt. As the gas exits the tube, it will bubble up through the melt.

Bubbling preferably can be allowed to continue for a sufficient time to effect removal of most, if not all, of the impurities in the melt. The amount of time necessary to remove all the targeted impurities can be determined by the amount of impurities in the starting raw material and the mass of the charge.

This bubbling technique can be performed under vacuum, reduced pressure, or at elevated pressures. Gas flows in between 0.001 cc/min to 1000 L/min can be used in accordance with this invention, however typically a gas flow of about 10 cc/min for about 1 hour should be sufficient to remove most of the impurities.

The technique can also be applied using one or more of a variety of spargers. For example, the container can have an inner bottom wall defining with the bottom of the container a plenum into which the scavenger gas is supplied under pressure sufficient to allow the gas to enter the melt. The inner bottom wall can be provided with a plurality of holes through which the gas can enter the chamber containing the molten growth material to be purified, whereupon the gas will bubble up through the melt. The container alternatively or additionally can be equipped with a sparger located at the bottom of the melt chamber for injecting the scavenger gas into melt.

If the crucible is sealed, the top thereof can be equipped with an exhaust port connected to a source of vacuum for withdrawing the reaction gases from the crucible. If the crucible is instead placed in a sealed furnace, the furnace can be equipped with an exhaust port connected to a source of vacuum for withdrawing the reaction gases from the furnace.

After the bubbling process, the scavenger gas flow is stopped and any utilized gas injector, such as the aforesaid hollow graphite tube, can be removed from the melt. At this point a crystal can be grown using any suitable growth process. Alternatively, the melt can be used to form a pre-growth material that can later be added to a growth furnace for subsequent melting followed by crystal growth.

The foregoing procedures preferably are applied singly or collectively to provide a purified melt from which a crystal is grown. Preferably the crystal is grown in a growth atmosphere free of undesirable impurities such as water, carbon monoxide, oxygen, carbon dioxide, nitric oxide, nitrogen dioxide, etc.

### EXAMPLE 1

68 kg of CaCO₃ and 1.9 kg of PbCO₃ is slurried in 100 L of water. Nitric acid is added until the pH is at or below 0.4. The solution is then heated to 85° C. and stirred for four hours until all of the powder is dissolved. While the solution is still hot, an aqueous solution of ammonium carbonate (0.5 kg/L) heated to 85° C. is added until the pH=8. The solution is mixed for an additional hour, and then allowed to cool and age for 16 hours. The supernatant liquid is removed from the coprecipitated carbonate powder, which is then washed four times with 120 L of water. The coprecipitated calcium-lead carbonate powder is then slurried with 160 L of water, and slowly added to 362 L of a 30% wt HF aqueous solution. The reaction is mixed for 3 hours, and then aged for 16 hours. The supernatant liquid is removed from the coprecipitated calcium-lead fluoride powder, and then washed three times with 120 L of water. The final powder is then filtered and dried at 150° C.

### EXAMPLE 2

68 kg of CaCO₃ and 1.7 kg of PbCO₃ is slurried in 160 L of water. The carbonate slurry is then added slowly to 362 L of a 30% wt HF aqueous solution. The reaction is mixed for 3 hours, and then aged for 16 hours. The intimately mixed calcium-lead fluoride powder is then washed three times with 120 L of water. The final powder is then filtered and dried at 150° C.

### EXAMPLE 3

134 kg of BaCO₃ and 3.8 kg of PbCO₃ are slurried together in 100 L of water. Nitric acid is added until the pH is at or below 0.4. The solution is then heated to 85° C. and stirred for four hours until all of the powder is dissolved. While the solution is still hot, an aqueous solution of ammonium carbonate (0.5 kg/L) heated to 85° C. is added until the pH=8. The solution is mixed for an additional hour, and then allowed to cool and age for 16 hours. The supernatant liquid is removed from the coprecipitated carbonate powder, which is then washed four times with 120 L of water. The coprecipitated barium-lead carbonate powder is then slurried with 160 L of water, then slowly added to 362 L of a 30% wt HF aqueous solution. The reaction is mixed for 3 hours, and then aged for 16 hours. The supernatant liquid is removed from the coprecipitated barium-lead fluoride powder, and then washed three times with 120 L of water. The final powder is then filtered and dried at 150° C.

### EXAMPLE 4

30 kg of MgCO₃ and 0.8 kg of PbCO₃ are slurried together in 99 L of water. After stirring for 1 hour, the solution is slowly added to 10 L of 48% wt HF aqueous solution. The reaction is mixed for 1.5 hours, and then allowed to settle. The supernatant is removed. 100 L of water is added to the reaction and the pH is adjusted to 2.5 with 40% NH₄OH aqueous solution, stirred for 1 hour, then left to settle for 16 hours. The supernatant is removed and the solution is washed two times with 100 L of water. To the magnesium-lead fluoride coprecipitated mixture, 2 L of a 40% NH₄F aqueous solution is added and the slurry is placed in trays and dried in an oven at 150° C. for 3 days.

### EXAMPLE 5

60 kg of the material produced in Example 1 was loaded into a crucible and slowly heated until melt under vacuum using known outgassing techniques. A crystal was grown using the Stockbarger crystal growth technique and cooled using a standard annealing procedures. The bulk absorption for a lens blank obtained, as by cutting, from the crystal was 0.01468%/cm at 193 nm. Previous crystals grown using prior art techniques without coprecipitation have produced lens blanks having an average bulk absorption of 0.025%/cm, with the best three crystals having values of 0.01649, 0.01789, and 0.01789%/cm at 193 nm wavelength over approximately a hundred growths.

Modifications, changes and improvements to the preferred forms of the invention herein disclosed, described and illustrated may occur to those skilled in the art who come to understand the principles and precepts thereof. Accordingly, the scope of the patent to be issued hereon should not be limited to the particular embodiments of the invention set forth herein, but rather should be limited by the advance by which the invention has promoted the art.

What is claimed is:

1. A fluoride crystal having a bulk absorption equal to or less than 0.015%/cm at a wavelength of 193 nm.

2. A fluoride crystal as set forth in claim 1, having a bulk absorption equal to or less than 0.014%/cm at a wavelength of 193 nm.

3. A fluoride crystal as set forth in claim 2, having a bulk absorption equal to or less than 0.013%/cm at a wavelength of 193 nm.

4. A fluoride crystal with properties as set forth in claim 1, grown from a growth material, wherein a fluoride of an alkaline- or alkali-earth metal has been coprecipitated from solution with a scavenger to form after separation an intimate dispersion of the scavenger with the alkaline- or alkali-earth metal fluoride.

5. A crystal as set forth in claim 4, wherein the scavenger included a metal fluoride.

6. A crystal as set forth in claim 5, wherein the scavenger was selected from the group consisting of lead fluoride or zinc fluoride.

7. A crystal as set forth in claim 4, wherein coprecipitation of the alkaline- or alkali-earth metal fluoride and the scavenger was performed using at least one of the chloride, nitrate, or carbonate salts of the alkaline- or alkali-earth metal and scavenger.

8. A crystal as set forth in claim 7, wherein the at least one of chloride, nitrate, hydroxide, or carbonate salts of the alkaline- or alkali-earth metal and scavenger was reacted in solution with hydrofluoric acid.

9. A crystal as set forth in claim 7, wherein the at least one of chloride, nitrate, hydroxide, or carbonate salts of the alkaline- or alkali-earth metal and scavenger are reacted in solution with a dissolved fluorine salt, such as ammonium fluoride or ammonium bifluoride.

10. A crystal as set forth in claim 4, wherein the growth material was a dried powder obtained by separating the coprecipitated crystals from solution and then drying the coprecipitated crystals.

11. A crystal as set forth in claim 3, wherein the crystal is an alkaline- or alkali-earth metal fluoride crystal.

12. A crystal as set forth in claim 11, wherein the alkaline- or alkali-earth metal is selected from a group consisting of calcium fluoride, barium fluoride, magnesium fluoride, strontium, and lithium fluoride.

13. A method of growing a fluoride crystal as set forth in claim 1, comprising the steps of placing a growth material in an enclosed space, heating the growth material, exhausting from an enclosed space scavenger gas produced by reaction of the scavenger with impurities in the growth material to form a higher purity growth material that is heated until molten, and then growing a fluoride crystal from the molten growth material.

14. A method of growing a fluoride crystal with improved radiation hardness, wherein a fluoride of an alkaline- or alkali-earth metal is coprecipitated from solution with a scavenger to form after separation an intimate dispersion of the scavenger with the alkaline- or alkali-earth metal fluoride to improve radiation hardness, and the intimate dispersion is used to grow the fluoride crystal.

15. A method as set forth in claim 14, wherein the intimate dispersion is loaded into a growth crucible as a dried powder, the dried powder is heated to form a melt, and a scavenger gas is introduced into the melt.

16. A method as set forth in claim 14, wherein coprecipitation of the alkaline- or alkali-earth metal fluoride and the scavenger is performed using at least one of the chloride, nitrate, or carbonate salts of the alkaline- or alkali-earth metal and scavenger.
